(19) United States
(12) Patent Application Publication
(10) Pub. No.: US 2018/0061979 A1
(43) Pub. Date: Mar. 1, 2018

(54) Method of Manufacturing a Superjunction Semiconductor Device and Superjunction Semiconductor Device

(71) Applicant: Infineon Technologies Austria AG, Villach (AT)

(72) Inventors: Hans Weber, Bayerisch Gmain (DE); Andreas Voerckel, Finkenstein (AT); Franz Hirler, Isen (DE); Maximilian Treiber, Munich (DE)

(21) Appl. No.: 15/683,844

(22) Filed: Aug. 23, 2017

(30) Foreign Application Priority Data
Aug. 25, 2016 (DE) 102016115759.7

(51) Int. Cl. H01L 29/78; H01L 29/06; H01L 21/308; H01L 21/02; H01L 29/66; H01L 29/417; H01L 21/78; H01L 29/10; H01L 21/225; H01L 21/324; H01L 21/265

(52) U.S. Cl. CPC H01L 29/7811; H01L 29/0696; H01L 21/308; H01L 21/02639; H01L 29/66712; H01L 29/41741; H01L 21/3065; H01L 29/0615; H01L 29/1095; H01L 29/0634; H01L 21/2252; H01L 21/324; H01L 21/26513; H01L 21/78

(57) ABSTRACT

A semiconductor device is manufactured in a semiconductor body of a wafer by forming a mask on a surface of the semiconductor body. The mask has a plurality of first mask openings in a transistor cell area and a mask opening design outside the transistor cell area. The mask opening design includes one second mask opening or a plurality of second mask openings encircling the transistor cell area. The plurality of second mask openings are consecutively arranged at lateral distances smaller than a width of the plurality of second mask openings. A plurality of first trenches are formed in the semiconductor body at the first mask openings. One or a plurality of second trenches are formed at the one or plurality of second mask openings. The first trenches and the and one or the plurality of second trenches are filled with a filling material including at least a semiconductor material.

### BACKGROUND

Semiconductor devices known as charge compensation or super junction (SJ) semiconductor devices, for example SJ insulated gate field effect transistors (SJ IGFETs) are based on mutual space charge compensation of n- and p-doped regions in a semiconductor substrate or body allowing for an improved trade-off between area-specific on-state resistance Ron×A and breakdown voltage Vbr between load terminals such as source and drain. Performance of charge compensation of SJ semiconductor devices depends on precision when setting a lateral or horizontal charge balance by the n-doped and p-doped regions and when reducing an electric field strength in an area outside a transistor cell area.

It is desirable to improve a method of manufacturing a super junction semiconductor device in regard to performance and to provide a related super junction semiconductor device.

### SUMMARY

The present disclosure relates to a method of manufacturing a semiconductor device in a semiconductor body of a wafer. The method comprises forming a mask on a surface of a semiconductor body. The mask comprises a plurality of first mask openings in a transistor cell area and a mask opening design outside the transistor cell area. The mask opening design includes one second mask opening or a plurality of second mask openings encircling the transistor cell area. The plurality of second mask openings are consecutively arranged at lateral distances smaller than a width of the plurality of second mask openings or smaller than a lateral distance between the first mask opening. The method further comprises forming a plurality of first trenches in the semiconductor body at the first mask openings, and forming one or a plurality of second trenches at the one or the plurality of second mask openings. The method further comprises filling the first trenches and the one or the plurality of second trenches with a filling material including at least a semiconductor material.

The present disclosure also relates to a vertical semiconductor device. The vertical semiconductor device comprises transistor cells in a transistor cell area of a semiconductor body. A first load terminal contact is at a first side of the semiconductor body and a second load terminal contact at a second side of the semiconductor body opposite to the first side. The vertical semiconductor device further comprises a super junction structure in the semiconductor body. The super junction structure comprises a plurality of first and second semiconductor regions of opposite first and second conductivity types, respectively, and alternately arranged along a lateral direction. A termination structure is between an edge of the semiconductor body and the transistor cell area. The vertical semiconductor device further comprises one or a plurality of third semiconductor regions encircling the transistor cell area and being of the first conductivity type, wherein the plurality of third semiconductor regions are consecutively arranged at lateral distances smaller than a width of the plurality of third semiconductor regions or smaller than a width of the second semiconductor regions.

The present disclosure also relates to another vertical semiconductor device. The vertical semiconductor device comprises transistor cells in a transistor cell area of a semiconductor body. A first load terminal contact at a first side of the semiconductor body and a second load terminal contact at a second side of the semiconductor body opposite to the first side. The vertical semiconductor device further comprises a super junction structure in the semiconductor body. The super junction structure comprises a plurality of first and second semiconductor regions of opposite first and second conductivity types, respectively, and alternately arranged along a lateral direction. A termination structure between an edge of the semiconductor body and the transistor cell area. The vertical semiconductor device further comprises one or a plurality of third semiconductor regions of the first conductivity type and encircling the transistor cell area. A minimum of a concentration profile of the first dopants of the first conductivity type along a width direction of the one or the plurality of third semiconductor regions is located in a center of the one or the plurality of third semiconductor regions, respectively.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the disclosure and are incorporated in and constitute a part of this specification. The drawings illustrate the embodiments of the present disclosure and together with the description serve to explain principles of the disclosure. Other embodiments and intended advantages will be readily appreciated as they become better understood by reference to the following detailed description.

FIG. 1A are schematic plan and cross sectional views of a semiconductor body after forming a mask comprising first and second mask openings on a surface.

FIG. 1B are schematic plan and cross sectional views of the semiconductor body of FIG. 1A after forming first and second trenches in the semiconductor body at the first and second mask openings, respectively.

FIG. 1C are schematic top and cross sectional views of the semiconductor layer of FIG. 1B after filling the first and second trenches with a filling material.

FIGS. 2A to 2C are schematic cross-sectional views for illustrating a method of forming a doped semiconductor layer on a semiconductor substrate by multiple epitaxial growth of semiconductor sub-layers and ion implantation of dopants into the semiconductor sub-layers.

FIG. 3 illustrates one embodiment of a super junction structure in the semiconductor body including subsequently arranged first and second semiconductor zones of different conductivity type.

FIG. 4 illustrates a schematic diagram of an example of a concentration profile of first and second dopant species along an intersection line FF′ illustrated in FIG. 3.

FIG. 5 illustrates a schematic diagram of an example of the concentration profile of the first and second dopant species along an intersection line GG′ illustrated in FIG. 3.

FIG. 6A illustrates a schematic diagram of a first example of a concentration profile of the first and second dopant species along an intersection line EE′ illustrated in FIG. 3.

FIG. 6B illustrates a schematic diagram of a second example of the concentration profile of the first and second dopant species along the intersection line EE′ of FIG. 3.

FIG. 7A illustrates a schematic diagram of a first example of a concentration profile of the first dopant and second dopant species along an intersection line HH′ illustrated in FIG. 3.

FIG. 7B illustrates a schematic diagram of a second example of the concentration profile of the first and second dopant species along an intersection line II′ illustrated in FIG. 3.

FIG. 8 illustrates a cross-sectional view of a super junction semiconductor device according to an embodiment of a vertical FET.

FIG. 9 illustrates a plan view of a the semiconductor body 106 of FIG. 1C having a minimum lateral distance 1 min between a dicing street and the one second trench.

FIG. 10 is a schematic cross sectional view of a super junction structure having a width of the one or the plurality of second trenches larger than a width of the first trenches in the transistor cell area.

FIG. 11 is a schematic plan view of a semiconductor body for illustrating a process of forming a termination structure in an edge termination area between the transistor cell area and the one or the plurality of second trenches.

FIGS. 12A and 12B illustrate simulated equipotential lines of a super junction semiconductor device in a blocking mode of the super junction semiconductor device.

FIGS. 13A to 13E illustrate schematic plan views of semiconductor devices including different layouts of third semiconductor regions encircling a transistor cell area.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may exist between the electrically coupled elements, for example elements that temporarily provide a low-ohmic connection in a first state and a high-ohmic electric decoupling in a second state.

The Figures illustrate relative doping concentrations by indicating “−” or “+” next to the doping type “n” or “p”. For example, “n−” means a doping concentration that is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The terms “wafer”, “substrate”, “semiconductor body” or “semiconductor substrate” used in the following description may include any semiconductor-based structure that has a semiconductor surface. Wafer and structure are to be understood to include silicon (Si), silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon germanium (SiGe), germanium (Ge) or gallium arsenide (GaAs). According to other embodiments, silicon carbide (SiC) or gallium nitride (GaN) may form the semiconductor substrate material.

The term “horizontal” as used in this specification intends to describe an orientation substantially parallel to a first or main surface of a semiconductor substrate or body. This can be for instance the surface of a wafer or a die.

The term “vertical” as used in this specification intends to describe an orientation which is substantially arranged perpendicular to the first surface, i.e. parallel to the normal direction of the first surface of the semiconductor substrate or body.

In this specification, a second surface of a semiconductor substrate or semiconductor body is considered to be formed by the lower or backside surface while the first surface is considered to be formed by the upper, front or main surface of the semiconductor substrate. The terms “above” and “below” as used in this specification therefore describe a relative location of a structural feature to another

In this specification, n-doped is referred to as first conductivity type while p-doped is referred to as second conductivity type. Alternatively, the semiconductor devices can be formed with opposite doping relations so that the first conductivity type can be p-doped and the second conductivity type can be n-doped.

Processing of a semiconductor wafer may result in semiconductor devices having terminal contacts such as contact pads (or electrodes) which allow electrical contact to be made with the integrated circuits or discrete semiconductor devices included in the semiconductor body. The electrodes may include one or more electrode metal layers which are applied to the semiconductor material of the semiconductor chips. The electrode metal layers may be manufactured with any desired geometric shape and any desired material composition. The electrode metal layers may, for example, be in the form of a layer covering an area. Any desired metal, for example Cu, Ni, Sn, Au, Ag, Pt, Pd, and an alloy of one or more of these metals may be used as the material. The electrode metal layer(s) need not be homogenous or manufactured from just one material, that is to say various compositions and concentrations of the materials contained in the electrode metal layer(s) are possible. As an example, the electrode layers may be dimensioned large enough to be bonded with a wire.

In embodiments disclosed herein one or more conductive layers, in particular electrically conductive layers, are applied. It should be appreciated that any such terms as “formed” or “applied” are meant to cover literally all kinds and techniques of applying layers. In particular, they are meant to cover techniques in which layers are applied at once as a whole like, for example, laminating techniques as well as techniques in which layers are deposited in a sequential manner like, for example, sputtering, plating, molding, CVD (Chemical Vapor Deposition), physical vapor deposition (PVD), evaporation, hybrid physical-chemical vapor deposition (HPCVD), etc.

The applied conductive layer may comprise, inter alia, one or more of a layer of metal such as Cu or Sn or an alloy thereof, a layer of a conductive paste and a layer of a bond material. The layer of a metal may be a homogeneous layer. The conductive paste may include metal particles distributed in a vaporizable or curable polymer material, wherein the paste may be fluid, viscous or waxy. The bond material may be applied to electrically and mechanically connect the semiconductor chip, e.g., to a carrier or, e.g., to a contact clip. A soft solder material or, in particular, a solder material capable of forming diffusion solder bonds may be used, for example solder material comprising one or more of Sn, SnAg, SnAu, SnCu, In, InAg, InCu and InAu.

A dicing process may be used to divide the semiconductor wafer into individual chips. Any technique for dicing may be applied, e.g., blade dicing (sawing), laser dicing, etching, etc. The semiconductor body, for example a semiconductor wafer may be diced by applying the semiconductor wafer on a tape, in particular a dicing tape, apply the dicing pattern, in particular a rectangular pattern, to the semiconductor wafer, e.g., according to one or more of the above mentioned techniques, and pull the tape, e.g., along four orthogonal directions in the plane of the tape. By pulling the tape, the semiconductor wafer gets divided into a plurality of semiconductor dies (chips).

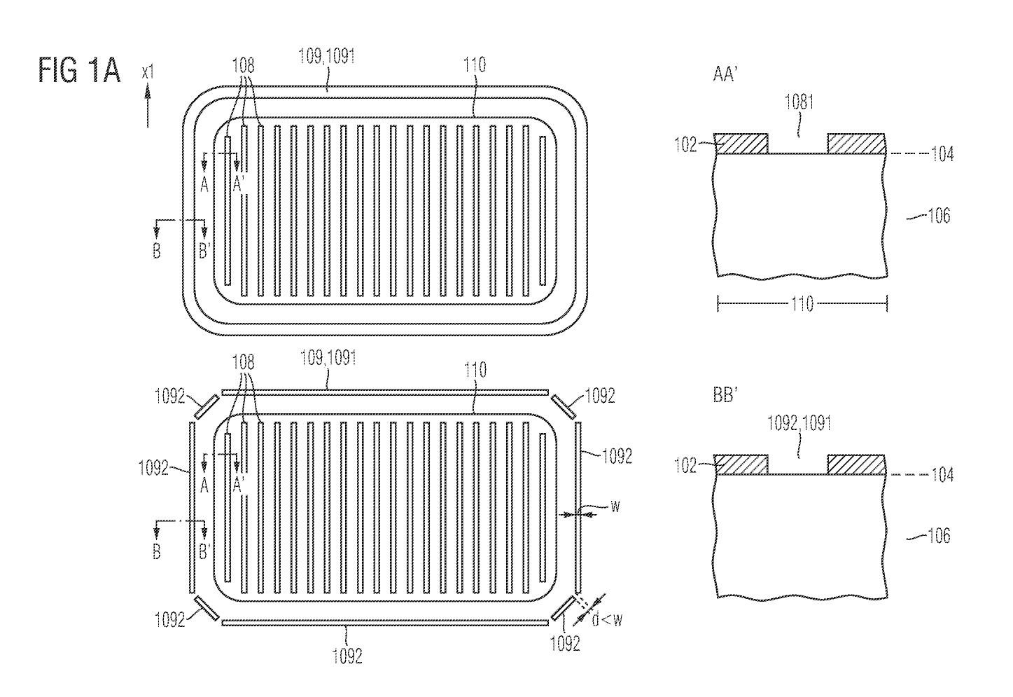

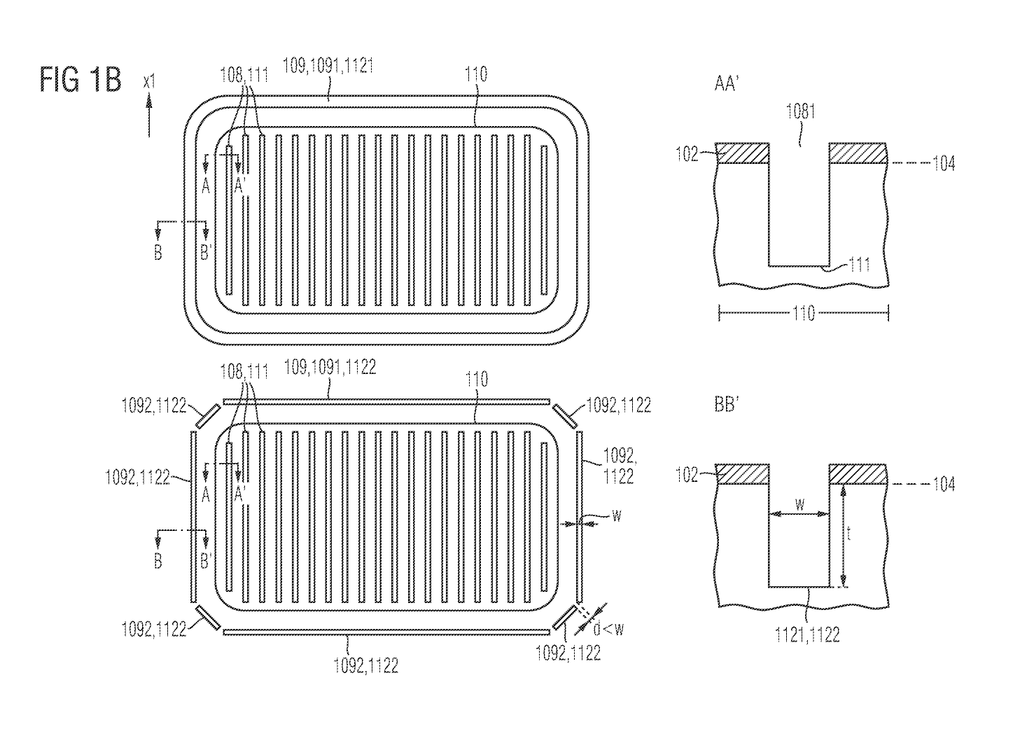

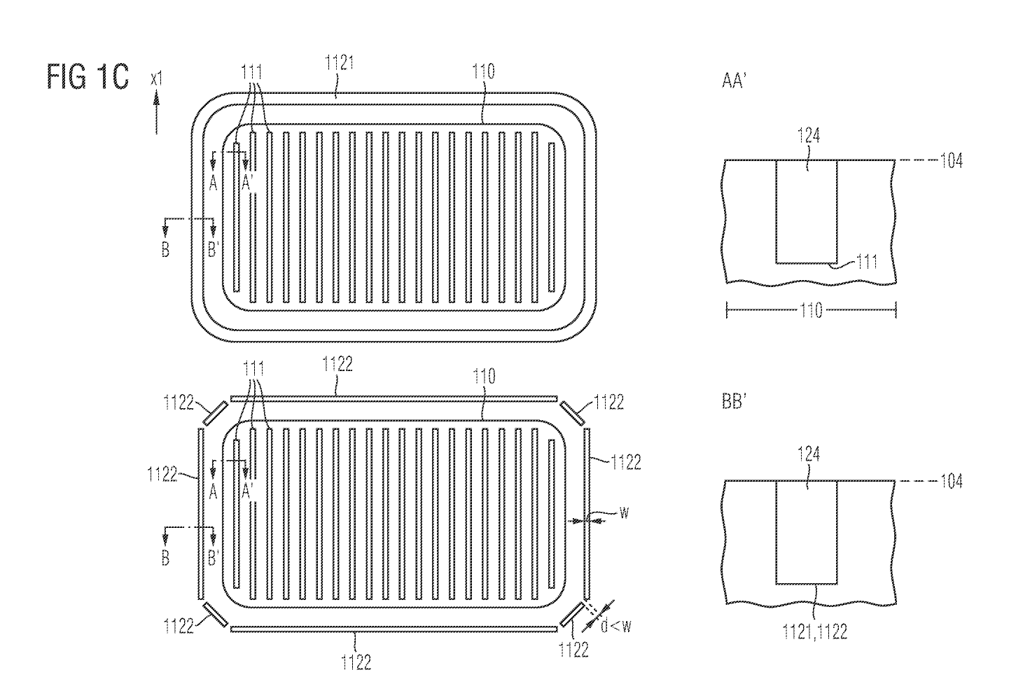

FIGS. 1A to 1C are schematic top and cross sectional views of a semiconductor body for illustrating an embodiment of a method of manufacturing a super junction semiconductor device.

It will be appreciated that while method is illustrated and described below as a series of acts or events, the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects of embodiments of the disclosure herein. Also, one or more of the acts depicted herein may be carried out in one or more separate act and/or phases.

Referring to the schematic plan and cross sectional views of FIG. 1A, a mask 102 is formed on a surface 104 of a semiconductor body 106. The mask 102 includes a plurality of first mask openings 108 in a transistor cell area 110 and a mask opening design 109 outside the transistor cell area 110. The plurality of first mask openings 108 extend along a first lateral direction x1. In the upper schematic plan view of FIG. 1A, the mask opening design 109 includes one second mask opening 1091 encircling the transistor cell area 110. In the bottom schematic plan view of FIG. 1A, the mask opening design 109 includes a plurality of second mask openings 1092 being consecutively arranged at lateral distances d smaller than a width w of the plurality of second mask openings 1092, i.e. d<w or smaller than a lateral distance between the first mask openings 108. A vast variety of specific arrangements of second mask openings 1092 may be applied provided that these second mask openings 1092 encircle the transistor cell area 110 at lateral distances d smaller than a width w of the plurality of second mask openings 1092, i.e. d<w, or smaller than a lateral distance between the first mask openings 108. In the embodiment illustrated in FIGS. 1A and 1B, the plurality of first mask openings 108 are stripe-shaped. In other embodiments, the plurality of first mask openings 108 may form a grid, be of circular shape, or of elliptic shape, or of other polygonal shape such as hexagonal shape.

Referring to the schematic top and cross sectional views of FIG. 1B, a plurality of first trenches 111 are formed in the semiconductor body 106 at the first mask openings 108. In the upper schematic plan view of FIG. 1B, one second trench 1121 is formed at the one second mask opening 1091 for example by an anisotropic etch process such as reactive ion etching (RIE). In the bottom schematic plan view of FIG. 1B, a plurality of second trenches 1122 are formed at the one or the plurality of second mask openings 1092. In some embodiments, a ratio of a depth t of the one or the plurality of second trenches 1121, 1122 to a width w of the one or the plurality of second trenches 1121, 1122 to is equal to or greater than five.

Referring to the schematic top and cross sectional views of FIG. 1C, the first trenches 111 and the one or the plurality of second trenches 1121, 1122 are filled with a filling material 124 including at least a semiconductor material. In some embodiments, the semiconductor material is an intrinsic or lightly doped semiconductor material formed in the first and second trenches 111, 1121, 1122 by an epitaxial growth process, for example by chemical vapor deposition (CVD) of silicon, for example by lateral epitaxial growth (LEG) of silicon.

In some embodiments, the semiconductor body is made of or includes silicon, an orientation of the first trenches 1111 is set to coincide with a {010} lattice plane, which may be beneficial with regard to a fill characteristic of the first trenches 1111, for example. The surface 104 may coincide with a {001} lattice plane, for example.

In some embodiments, the semiconductor body 106 includes a semiconductor layer on a semiconductor substrate, the semiconductor layer comprising n- and p-type dopants.

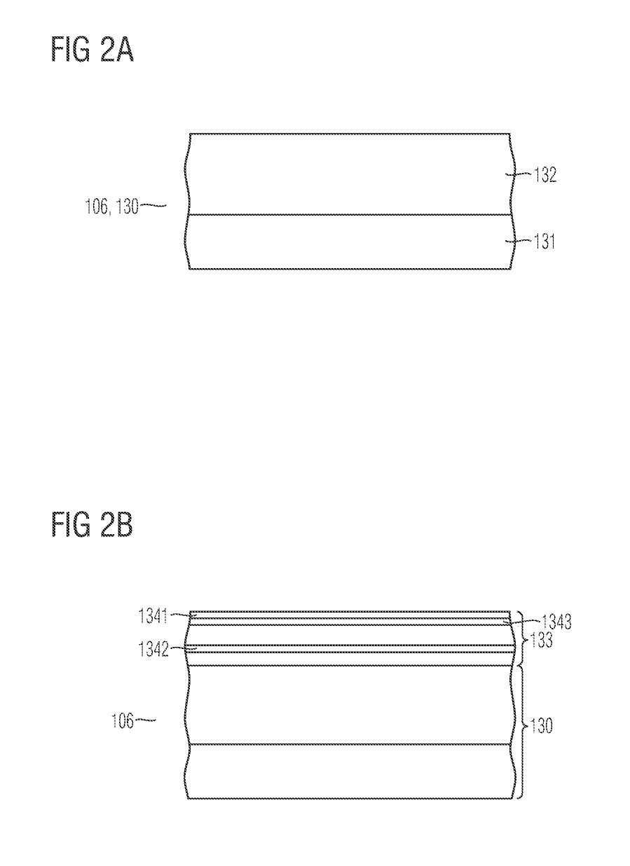

Referring to the schematic cross sectional view illustrated in FIG. 2A, a semiconductor substrate 130 comprising a highly doped semiconductor carrier 131 and one or more functional semiconductor layers 132, for example field stop region(s) and/or pedestal layer(s) for adjusting a profile of electric field strength may be provided as the semiconductor body 106.

Referring to the schematic cross sectional views of FIGS. 2B and 2C, a thickness of the semiconductor body 106 is increased by forming a semiconductor sub-layer 133 on a process surface of the semiconductor body 106. n- and p-type dopants are formed within the semiconductor sub-layer 133 by implanting the n- and/or p-type dopants into the semiconductor sub-layer 133. The n- and p-type dopants may be implanted one or multiple times at one or different implant energies and/or implant doses. Ion implantation at different energies may result in different implant depths as is illustrated in FIG. 2B with respect to implant regions 1341, 1342. The implant energy associated with introduction of the dopants of the implant region 1342 is larger than the implant energy associated with the introduction of the dopants of the implant region 1341 or an implant region 1343 of opposite conductivity type than the implant regions 1341, 1342. Apart from ion implantation, other doping processes, for example in-situ doping or doping from a solid doping source may be used to form one or more of the implant regions 1341, 1342, 1343.

In some embodiments, the process surface during dopant implantation of the ion implantation processes illustrated with reference to FIG. 2B is free of an ion implantation mask in the transistor cell area, or even free of any patterned ion implantation mask anywhere on the process surface.

Referring to the schematic cross sectional view of FIG. 2C the processes of semiconductor sub-layer formation and ion implantation of n- and p-type dopants may be repeated several times for adapting a vertical extension of the super junction structure in conjunction with implantation doses of the n- and p-type dopants to a desired drain to source blocking voltage of the final device. Examples of drain to source blocking voltage or device voltage classes include blocking voltages in the range of hundreds of volts, for example 400V, 500V, 600V, 650V, 700V, 800V, 900V, 1000V. In some embodiments, a thickness of each one of the semiconductor sub-layers 133 is set in a range 1 μm to 15 μm, for example in a range from 2 μm to 8 μm.

In some embodiments, an overall implant dose of the n- and p-type dopants into all of the semiconductor sub-layers 133 differs by at least 20%. In other words, an overall dose of the n- and p-type dopants determined by integrating a concentration of the n- and p-type dopants along a vertical extension of the super junction structure differs by at least 20%.

The semiconductor body 106 formed by the processes as described with reference to FIGS. 2A to 2C may be subject to the processes as described with reference to FIGS. 1A to 1C. Before carrying the processes as described with reference to FIGS. 1A to 1C, a diffusion process, for example a vertical diffusion process may be carried out for adjusting a vertical profile of dopant concentration of the dopants introduced into the implant regions 1341, 1342, 1343.

Further processes may be carried out subsequent to the processes illustrated in FIGS. 1A to 1C.

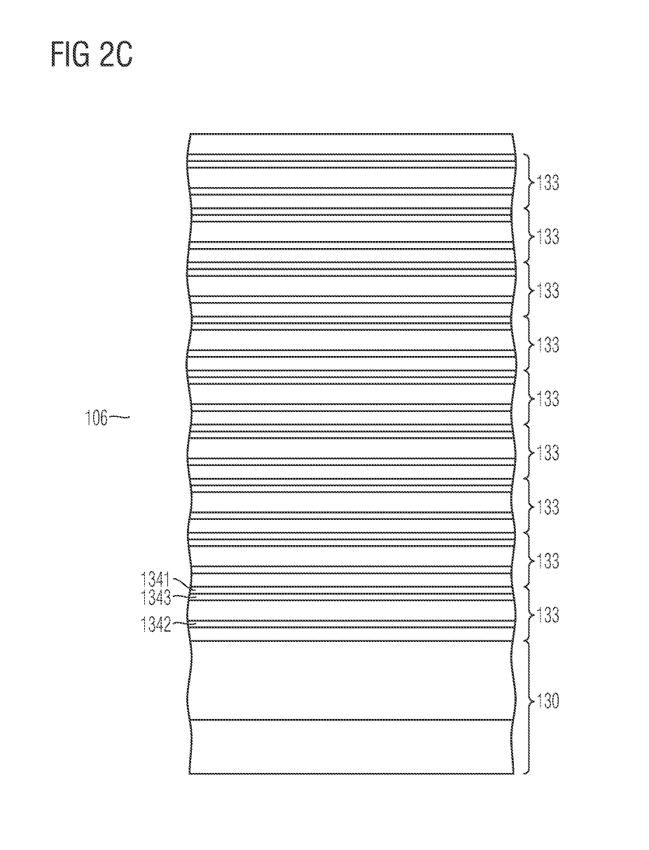

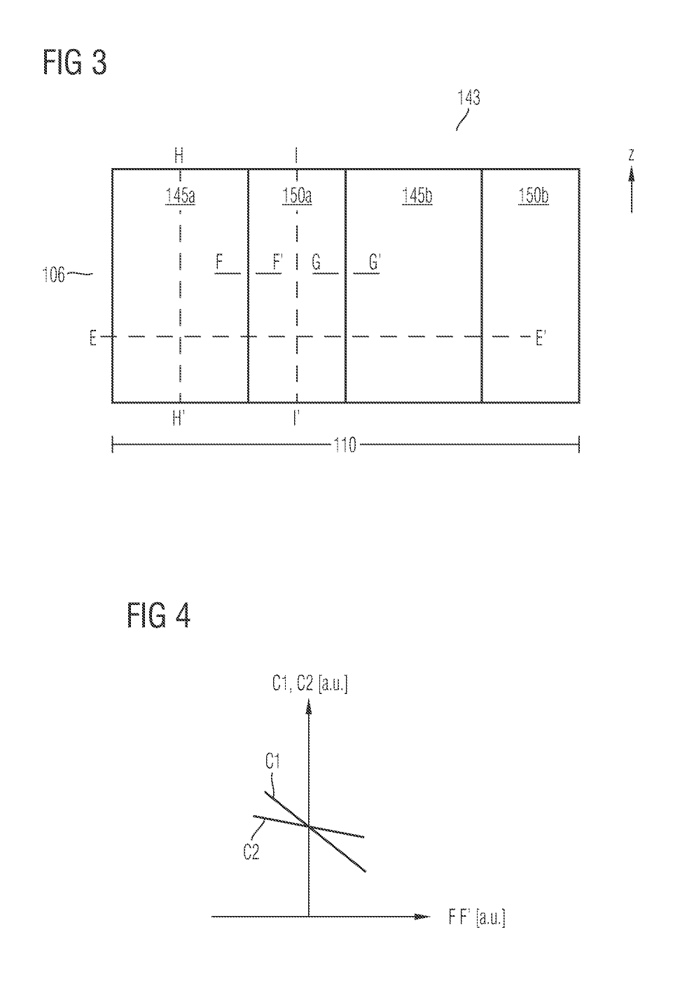

In some embodiments, the further processes include forming a super junction structure by heating the semiconductor body 106 so as to cause a diffusion process, for example a lateral diffusion of the n- and p-type dopants introduced into the semiconductor body 106 by processes as illustrated, by way of example, in FIGS. 2A to 2C. These dopants may diffuse into the filling material 124 illustrated in FIG. 1C at different amounts due to different diffusion velocities, thereby forming net p- and n-doped regions, for example. Referring to the schematic cross sectional view of the semiconductor body 106 illustrated in FIG. 3, the lateral diffusion process in the transistor cell area 110 may result in a super junction structure 143 including first semiconductor zones 145a, 145b of a first conductivity type and second semiconductor zones 150a, 150b of a second conductivity type different from the first conductivity type. The first and second semiconductor zones are alternately arranged along a lateral direction extending in parallel to a front surface of the semiconductor body 106, for example along the intersection line AA′ illustrated in FIG. 1A. The sequence of arrangement of these zones along the lateral direction is first semiconductor zone 145a, second semiconductor zone 150a, first semiconductor zone 145b, second semiconductor zone 150b.

Each of the first semiconductor zones 145a, 145b includes a first dopant species of the first conductivity type and a second dopant species of the second conductivity type. Since each of the first semiconductor zones 145a, 145b is of the first conductivity type, a concentration of the first dopant species is larger within these zones than the concentration of the second dopant species.

Each of the second semiconductor zones 150a, 150b includes the second dopant species. These second semiconductor zones 150a, 150b may also include the first dopant species in a concentration lower than the concentration of the second dopant species.

One of the first and second semiconductor zones, i.e., the first semiconductor zones 145a, 145b or the second semiconductor zones 150a, 150b, constitute drift zones of the super junction semiconductor device. A diffusion coefficient of the second dopant species is based on predominantly interstitial diffusion. As an example, the second dopant species may be boron or aluminum, for example.

A super junction semiconductor device including the super junction structure 143 illustrated in FIG. 3 may include further structural elements not illustrated in FIG. 3, either because these elements are located in a device portion different from the portion illustrated in FIG. 3 or because these elements are not illustrated for reasons of clarity. Examples for these elements not illustrated in FIG. 3 depend on the type of the device and may include one or a plurality of edge termination structures, measures for increasing avalanche robustness, semiconductor structures including body and source, drain, anode, cathode, gate structures including gate dielectrics and gate electrodes, insulation dielectrics, conductive structures such as contact plugs and metal layers, for example.

The first conductivity type may be an n-type and the second conductivity type may be a p-type. As a further example, the first conductivity type may be the p type and the second conductivity type may be the n-type.

The first and second semiconductor zones 145a, 145b, 150a, 150b constitute semiconductor drift- and compensation zones of different conductivity type. In a reverse operation mode of the device, an overall space charge of at least one of the first semiconductor zones may electrically compensate the space charge of at least one of the second semiconductor zones. An electrically active dose of at least one of the first semiconductor zones may also be smaller than 20%, or 10% or even 5% than the corresponding dose of one of the second semiconductor zones, whereby dose means ∫ (dN/dx) in the first or second semiconductor zones in the lateral direction, N being the effective or net concentration of n-type of p-type doping.

Examples of materials of the first and second dopant species may include As and B, As and Al, Sb and B, Sb and Al.

One of the first and second semiconductor zones 145a, 145b, 150a, 150b may include at least one epitaxial semiconductor layer grown on a semiconductor substrate along a vertical direction z perpendicular to a lateral direction, for example as illustrated in FIGS. 2A to 2C. The other one of the first and second semiconductor zones 145a, 145b, 150a, 150b may be arranged within the first trenches 111 formed within the semiconductor body 106. These zones may include epitaxial semiconductor layers grown on sidewalls of the trenches along the lateral direction. A width of the first semiconductor zones 145a, 145b may be greater than a width of a mesa region between neighboring trenches, for example.

The first and/or second dopant species may be implanted into the semiconductor body 106 as illustrated and described with reference to FIGS. 2A to 2C, for example.

FIG. 4 illustrates a schematic diagram of an example of a concentration profile of the first and second dopant species C1, C2 along the lateral direction of intersection line FF′ illustrated in FIG. 3.

A concentration C1 of the first dopant species having the first conductivity type is larger within the first semiconductor zone 145a (i.e., left part of graph illustrated in FIG. 4) than the concentration C2 of the second dopant species having the second conductivity type. Contrary thereto, the concentration C2 of the second dopant species is larger within the second semiconductor zone 150a (i.e., right part of graph illustrated in FIG. 4) than the concentration C1 of the first dopant species within this zone. Thus, the conductivity type of first semiconductor zone 145a corresponds to the conductivity type of the first dopant species and the conductivity of the second semiconductor zone 150a corresponds to the conductivity type of the second dopant species.

In other words, a concentration of the dopants of each of the first and second species at an interface between one of the first semiconductor zones 145a, 145b and one of the second semiconductor zones 150a, 150b is decreasing along the lateral direction from the first to the second semiconductor zones. The dopant profiles intersect at the interface, whereas a gradient of the profile is larger for the first dopant species than the second dopant species.

FIG. 5 illustrates a schematic diagram of an example of a profile of concentration C1, C2 of the first and second dopant species along the lateral direction of intersection line GG′ illustrated in FIG. 3.

A concentration C1 of the first dopant species is larger within the first semiconductor zone 145b (i.e. right part of graph illustrated in FIG. 5) than the concentration C2 of the second dopant species. Contrary thereto, the concentration C2 of the second dopant species is larger within the second semiconductor zone 150a (i.e., left part of graph illustrated in FIG. 5) than the concentration C1 of the first dopant species. Thus, a conductivity type of the first semiconductor zone 145b corresponds to the conductivity type of the first dopant species and the conductivity type of the second semiconductor zone 150a corresponds to the conductivity type of the second dopant species.

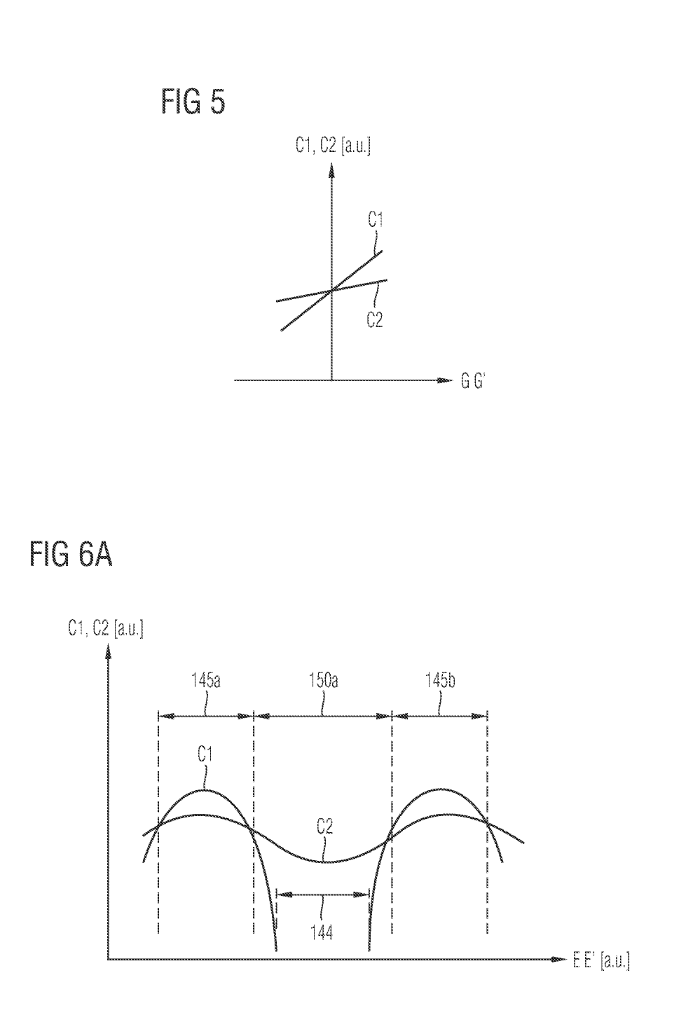

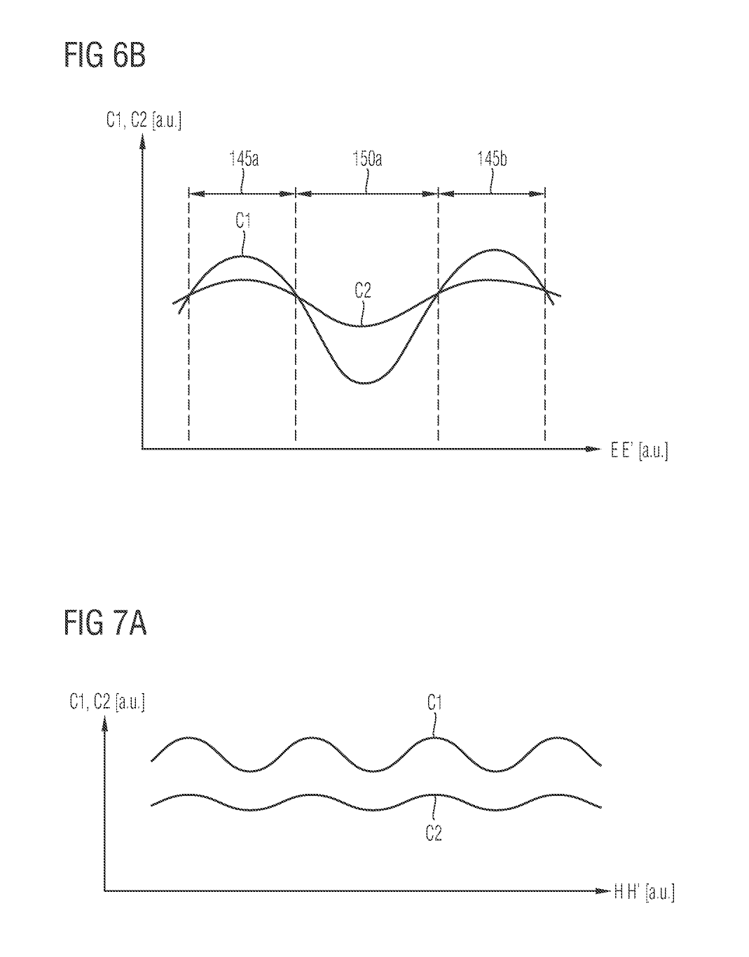

FIG. 6A illustrates one example of a profile of concentrations C1, C2 of first and second dopant species along the lateral direction of intersection line EE′ of the semiconductor body 106 illustrated in FIG. 3.

An intersection area between the profile of concentration C1 of the first dopant species and the profile of concentration C2 of the second dopant species defines an interface between a first semiconductor zone such as the first semiconductor zone 145a having a concentration C1 of the first dopant species that is larger than the concentration C2 of the second dopant species and a second semiconductor zone such as second semiconductor zone 150a having a concentration C2 of the second dopant species that is larger than the concentration C1 of the first dopant species. A schematic profile of concentrations C1, C2 as illustrated in FIG. 6A may be manufactured by diffusing first and second dopant species from a volume of the first semiconductor zones such as the first semiconductor zones 145a, 145b into a volume of the second semiconductor zone such as the second semiconductor zone 150a, which may be originally undoped and formed as is illustrated in FIG. 3. A width of the first semiconductor zones 145a, 145b may be greater than a width of a mesa region between neighboring trenches, for example.

In the example illustrated in FIG. 6A, a diffusion coefficient of the second dopant species is at least twice as large as the diffusion coefficient of the first dopant species. A maximum of the concentration of dopants C1, C2 of each of first and second dopant species along the lateral direction EE′ is located in the center of each of the first semiconductor zones 145a, 145b having a same lateral distance to the neighboring ones of the second semiconductor zones. A minimum of the concentration C2 of the second dopant species is located in the center of each of the second semiconductor zones such as the second semiconductor zone 150a having a same lateral distance to the neighboring ones of the first semiconductor zones such as the first semiconductor zones 145a, 145b.

In the example illustrated in FIG. 6A, a region 144 free of first dopant species remains within each of the second semiconductor zones such as the second semiconductor zone 150a. A corrugation of each of the profile of concentration C1, C2 may be influenced by a plurality of parameters such as dimensions and distance of the regions acting as a diffusion reservoir, diffusion coefficients of the respective dopant species or thermal budget and time of diffusion of the respective species, for example.

The schematic diagram of FIG. 6B illustrates another example of a profile of concentrations C1, C2 along the lateral direction of intersection line EE′ of the super junction structure 143 illustrated in FIG. 3. With regard to the location of maxima and minima of the profile of concentration C2 of the second dopant species is similar to the example illustrated in FIG. 6A.

The profile of concentration C1 of the first dopant species differs from the corresponding profile illustrated in FIG. 6A in that the first dopant species are located in an overall volume of second semiconductor zones such as the second semiconductor zone 150a. Thus, diffusion of the first dopant species out of neighboring diffusion reservoirs such as reservoirs located within first semiconductor zones 145a, 145b, is effected such that the two diffusion profiles will overlap and no semiconductor volume such as the region 144 free of first dopant species remains with the second semiconductor zones such as the second semiconductor zone 150a illustrated in FIG. 6A.

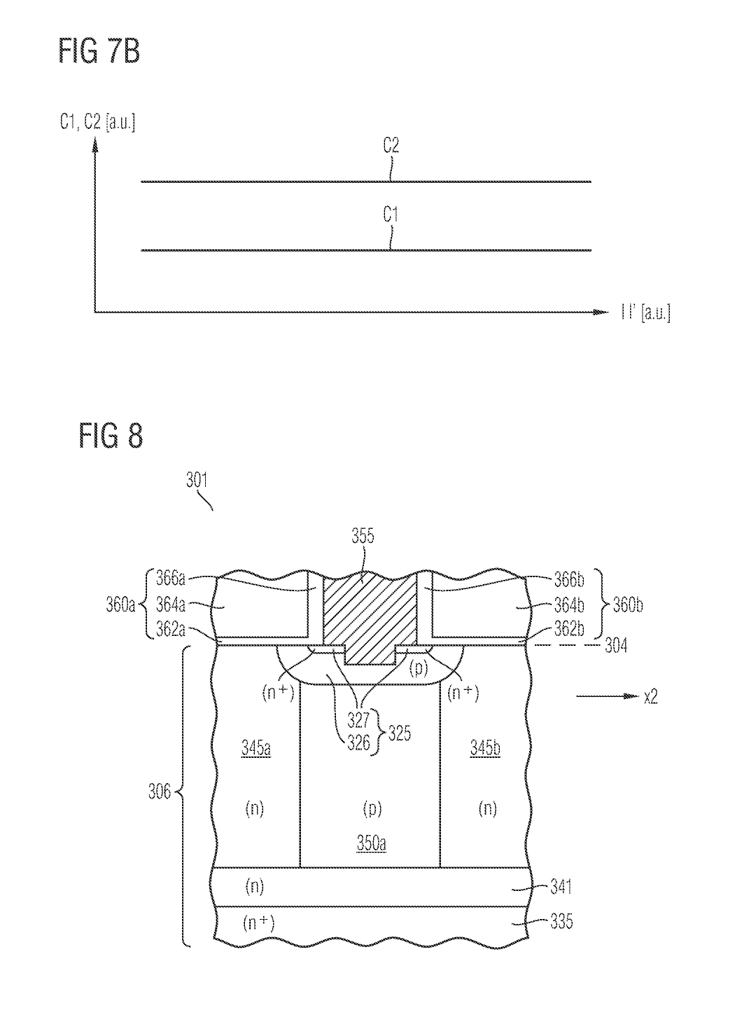

FIG. 7A illustrates one example of a profile of concentrations C1, C2 of the first and second dopant species along a vertical direction z of intersection line HH′ of the super junction structure 143 illustrated in FIG. 3. The profile of concentrations C1, C2 of the first and second dopant species along the vertical direction z of intersection line HH′ may be set by carrying out a diffusion process, for example a vertical diffusion process before the lateral diffusion process described with reference to FIGS. 3 to 6B.

Both, the profile of concentration C1 of the first dopant species and the profile of concentration C2 of the second dopant species include maxima and minima along the vertical direction z of the intersection line HH′. The concentration C1 of the first dopant species is larger than the concentration C2 of the second dopant species. Thus, a conductivity type of this first semiconductor zone 145a equals the conductivity type of the first dopant species.

The number of maxima of the concentration profiles C1, C2 of each of the first and second dopant species along the vertical direction z of the intersection line HH′ may correspond to the number of epitaxial semiconductor sub-layers formed on a semiconductor substrate, for example by processes as illustrated in FIGS. 2A to 2C. The first and second dopant species may be implanted into each of the semiconductor epitaxial layers. Each implant into one of the semiconductor epitaxial layers may be carried out after formation of the one of the semiconductor epitaxial layers and before formation of the next one of the epitaxial semiconductor layers, for example. An implant dose of the first species may be equal to the implant dose of the second dopant species. These doses may also be nearly the same differing from each other by less than 20%, or 10%, or 5%, or 3% or 1% for at least one of the epitaxial semiconductor layers. By varying the doses, for example greater p-than n-doses in an upper half of the epitaxial layer(s) and greater n-than p-doses in a lower half of the epitaxial layer(s), a charge imbalance may be adjusted, for example an imbalance caused by excess p-charge in the upper half of the epitaxial layer(s) and a charge imbalance caused by excess n-charge in the lower half of the epitaxial layer(s). As an example, by adjusting the implant doses of the first and second dopant species to different values, e.g., to above embodiment values, a production tolerance with regard to the breakdown voltage of the resulting device may be improved. The maxima of the profile of concentration C1, C2 of the first and second dopant species may be shifted from each other along the vertical direction z subject to implant energies chosen for implant of the first and second dopant species, for example. An overall implant per sub-layer may also be divided into a plurality of sub-doses at different implant energies, for example.

Associated with the example of profiles of concentration C1, C2 illustrated in FIG. 7A is a profile of concentration C1, C2 of first and second dopant species along the vertical direction z of an intersection line HH′ in the super junction structure 143 of FIG. 3. This profile may also include maxima and minima along the vertical direction z of the intersection line HH′. In contrast to the relation C1>C2 holding true for the profiles along the vertical direction HH′ illustrated in FIG. 7A, C2>C1 may apply for the profiles along the vertical direction z of intersection line II′ of FIG. 3 (not illustrated in FIG. 7A).

FIG. 7B illustrates another example of a profile of concentrations C1, C2 along the vertical direction z of the intersection line II′ in the super junction structure 143 of FIG. 3. In the embodiment illustrated in FIG. 7B, maxima caused by vertical diffusion of the dopant species are no longer present due to a constant or almost constant profile of the concentrations C1, C2.

In some other embodiments, and different from the example of profiles illustrated in FIG. 7A, the concentration profile C2 of the second dopant species having the larger diffusion coefficient includes less maxima along the vertical direction z than the concentration profile C1 of the first dopant species. This may be achieved by using plural implant energies when implanting the second dopant species and/or, when forming a plurality of semiconductor epitaxial layers constituting the first semiconductor zones 145a, 145b, by implanting the second dopant species into less of these epitaxial layers than the first dopant species. One or both of these profiles may also slightly vary along the vertical direction z, e.g. by a fraction of 5%, or 10% or 20%. Such variations may allow to improve the avalanche robustness of the device or to improve the production tolerance with regard to the breakdown voltage of the device. As an example a concentration of the one of the dopants constituting the drift zone may have a peak maximum along the vertical direction z which is higher than the other maxima, e.g., in a center of the drift zone along the vertical direction z. This example may allow for improving avalanche robustness of the device. As another example, a concentration of the one of the dopants constituting the drift zone may have a peak maximum at or close to a top side and/or bottom side of the drift zone, the peak maximum being higher than the other maxima in the vertical direction. This further example may allow for counterbalancing vertical diffusion of dopants out of the drift zones to be formed.

Associated with the example of profiles of concentration C1, C2 illustrated in FIG. 7B are profiles of concentration C1, C2 of first and second dopant species along the vertical direction z in the semiconductor body 106 of FIG. 3. In contrast to the relation C1>C2 holding true for the profiles along the vertical direction z of the intersection line HH′ of FIG. 3 as is illustrated in FIG. 7A, C2>C1 may apply for the profiles along the vertical direction z along the intersection line II′ of FIG. 3 as is illustrated in FIG. 7B.

Other examples of profiles of dopant concentrations C1, C2 along the vertical direction z may include parts having maxima and minima and other parts of constant dopant concentration. Such profiles may be manufactured by a combination of in-situ doping in the epitaxial layer deposition process and doping by ion implantation of dopants, for example. Further processes may follow for finalizing the super junction semiconductor device. Examples of further processes include formation of gate dielectric, gate electrode, load terminals at opposite surfaces of the semiconductor body and wiring areas, planar termination structures, for example one or more of a potential ring structure and a junction termination extension structure, thermal processing for vertical inter-diffusion of dopants of the implant regions.

FIG. 8 illustrates a schematic cross-sectional view of a portion of a vertical FET 301 including n-type first semiconductor zones 345a, 345b and p-type second semiconductor zone 350a. These semiconductor zones are arranged sequentially along a lateral direction x2 in the sequence of first semiconductor zone 345a, second semiconductor zone 350a and first semiconductor zone 345b. The profile of concentrations of the first and second dopant species within these semiconductor zones may correspond to any of the respective examples above. The first semiconductor zones 345a, 345b constitute drift zones of FET 301. In a reverse operation mode of FET 301, free carriers may be removed from these regions and charge compensation between the first and second semiconductor zones may be achieved, i.e., the space charge of one of the first zones may electrically compensate the space charge of one of the second zones.

FET 301 includes a semiconductor structure 325 having a p-type body region 326 and n+-type source region 327 formed at a front surface 304 of a semiconductor body portion 306.

An n+-type drain 335 is formed at a back surface of the semiconductor body portion 306 opposite to the front surface 304. An n-type semiconductor zone 341 may be arranged between the first and second semiconductor zones 345a, 345b, 350a and the n+ type drain 345. The n-type semiconductor zone 341 may have a concentration of dopants equal to the first semiconductor zones 345a. According to another example, a concentration of dopants of the n-type semiconductor zone 341 may be higher or lower than the concentration of the first semiconductor zones 345a, 345b. The n-type semiconductor zone 341 may be a field stop zone configured to improve robustness such as avalanche robustness of FET 301.

At the front surface 304, a conductive structure 355 is electrically coupled to the semiconductor structure 325. The conductive structure 355 may include conductive elements such as contact plugs and conductive layers of conductive material such as metals and/or doped semiconductors. The conductive structure 355 is configured to provide an electrical interconnection between FET 301 and further elements such as further circuit devices or chip pads, for example.

FET 301 also includes gate structures 360a, 360b including gate dielectrics 362a, 362b, gate electrodes 364a, 364b and insulating layers 366a, 366b.

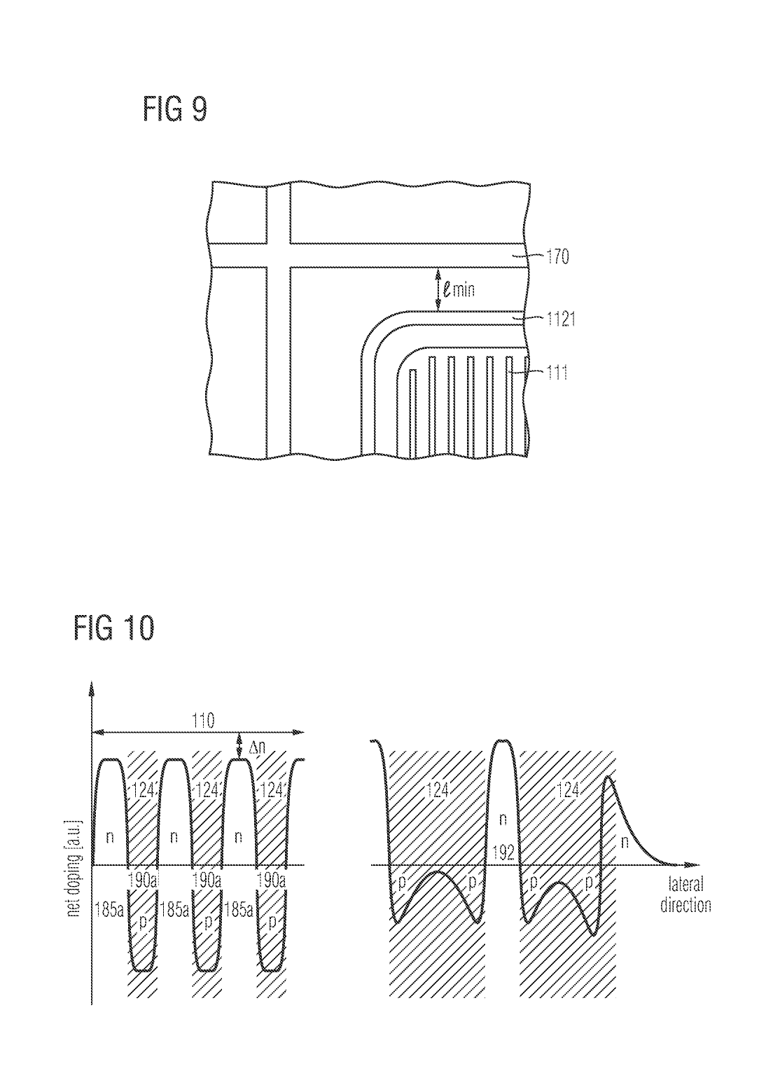

In the schematic plan view of FIG. 9 illustrating a part of the semiconductor body 106 while manufacturing the semiconductor device, a minimum lateral distance 1 min between a dicing street 170 and the one or the plurality of second trenches, for example the one second trench 1121 is set smaller than 100 μm. Hence, the one or the plurality of second trenches are placed close to a chip edge for limiting an extension of a space charge region toward the chip edge.

In some embodiments, a width of the one or the plurality of second trenches is set larger than a width of the plurality of first trenches. The schematic graph of FIG. 10 illustrates a net doping concentration profile of a semiconductor device based on process parameters for manufacturing the device. The left part of FIG. 10 illustrates net doping profiles in the transistor cell area 110, for example along a direction parallel to the intersection line EE′ of FIG. 3. The super junction structure exemplified by n-doped regions 185a, 185b, 185c and p-doped regions 190a, 190b, 190c may result from manufacturing processes as illustrated in FIGS. 1A to 3. When manufacturing the semiconductor device in silicon based on p-type dopants having larger diffusion coefficients than n-type dopants, for example boron as p-type dopant and antimony or arsenic as n-type dopants, more p-type dopants than n-type dopants will diffuse into the filling material 124, for example intrinsic or lightly doped silicon. This results in a net p-doping in at least part of the filling material 124 filled into the one or the plurality of second trenches 1121, 1122 (see FIGS. 1B, 1C), and to a net n-doping in a part of semiconductor body 106 surrounding the one or the plurality of second trenches 1121, 1122. When setting a width of the one or the plurality of second trenches 1121, 1122 larger than a width of the first trenches 111 in the transistor cell area 110 as is illustrated in FIG. 10, less p-type dopants will reach a center of a filled trench region from neighboring mesa regions, thereby resulting in a larger net n-doping in a doped region 192 than in any of the n-doped regions 185a, 185b, 185c in the transistor cell area 110. The net n-doping in the doped region 192 is larger than the net n-doping in the n-doped regions 185a, 185b, 185c in the transistor cell area 110 by a difference Δn. In the embodiment illustrated in FIG. 10, the net n-doped region 192 is sandwiched between second trenches filled with the filling material 124 that is net p-doped due to diffusion of more p-type dopants than n-type dopants from a surrounding part of the semiconductor body 106. The net n-doped region 192 may be manufactured by the method illustrated in FIGS. 1A to 1C, and a lateral diffusion process, and may be located at a position between neighboring two mask opening designs 109, wherein one of the neighboring two mask opening designs surrounds the transistor cell area 110 at a larger distance than the other one of the two mask opening designs 109.

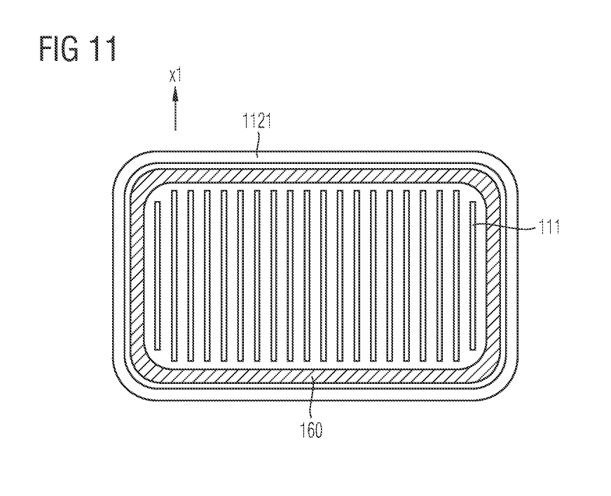

In some embodiments, for example as is illustrated in the schematic plan view of FIG. 11, the method further comprises forming a termination structure in an edge termination area 160 between the transistor cell area 110 and the one or the plurality of second trenches 1121, 1122. The termination structure aims at lowering electric field strength in the chip edges, thereby relieving the chip edges from high electric fields. In some embodiments, the termination structure is formed as one or more of a potential ring structure and a junction termination extension structure.

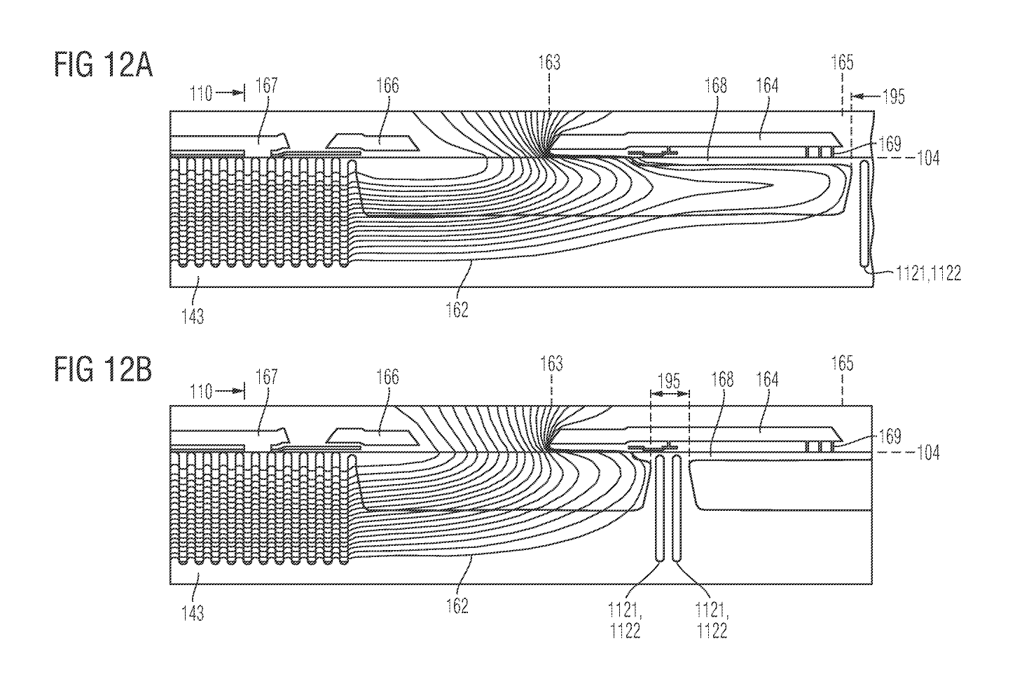

FIGS. 12A and 12B illustrate simulated equipotential lines 162 of super junction semiconductor devices comprising the filling material 124 in the one or plurality of second trenches 1121, 1122 as is illustrated in FIGS. 3, 10, for example. The simulated equipotential lines 162 extend from the transistor cell area 110 toward an edge of the chip in the right part of FIGS. 12A and 12B. The one or plurality of second trenches 1121, 1122 filled with the filling material may be p-doped caused by the lateral diffusion process as described with reference to FIGS. 3 to 6B, and a part of the semiconductor body in a surrounding area 195 of the second trenches 1121, 1122 may be n-doped and act as a lateral field stop region arranged in an area laterally confined by a dicing street for chip individualization as is illustrated in FIG. 9 and an inner edge 163 of a drain ring structure 164. The inner edge 163 of the drain ring structure 164 is closer to the transistor cell area 110 than an outer edge 165 of the drain ring structure 164. The drain ring structure 164 as well as a gate ring structure 166 and a source electrode 167 may be formed of one or more conductive materials, for example patterned parts of a same metallization layer or a metallization layer stack. The lateral field stop region keeps the equipotential lines away from chip edges and directs the equipotential lines toward the surface 104 in an area between the drain ring structure 164 and the gate ring structure 166. Thereby, an electric path configured to guide a drain potential from a rear side of the semiconductor body 106 to the surface 104 is provided, hindering the space charge region to extend to the chip edges at operation conditions based on applied blocking voltages.

The super junction semiconductor device may also include a doped well region at least partly overlapping a projection of the drain ring structure 164 onto the surface 104, the doped well region 168 and a drift zone of the semiconductor device having a same conductivity type. The doped well region 168 and the drain ring structure 164 may be electrically connected, for example by a contact 169. The doped well region 168 may also be located outside the drain ring structure 164, and may overlap a projection of the plurality of second trenches 1121, 1122 in a plan view onto the surface 104.

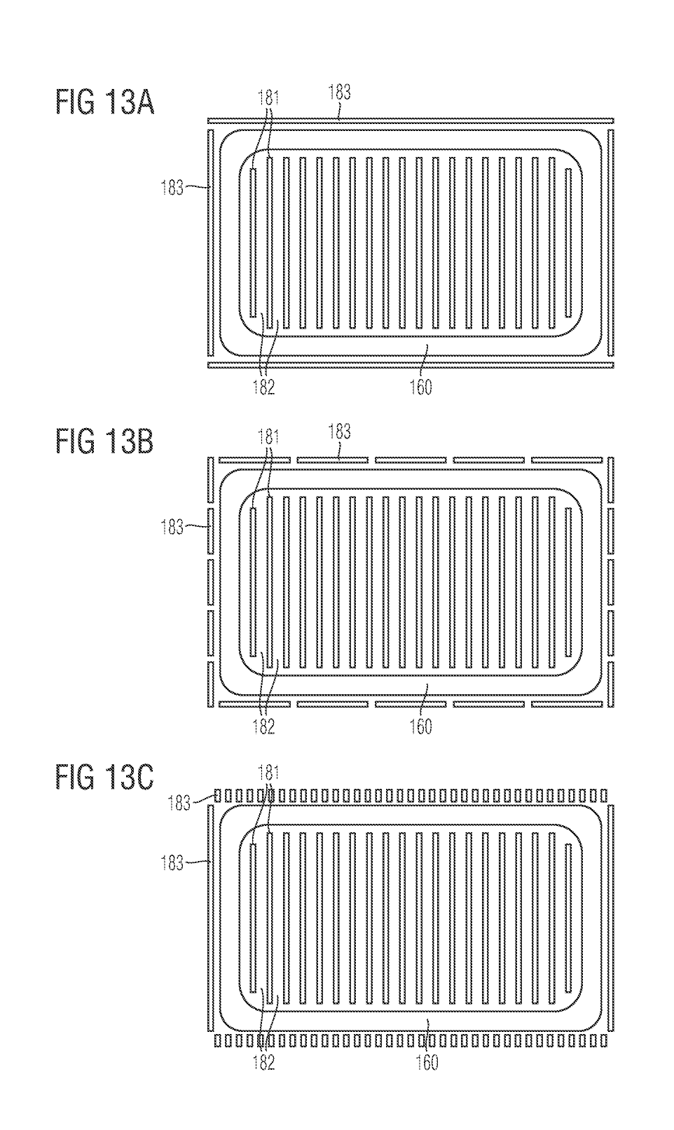

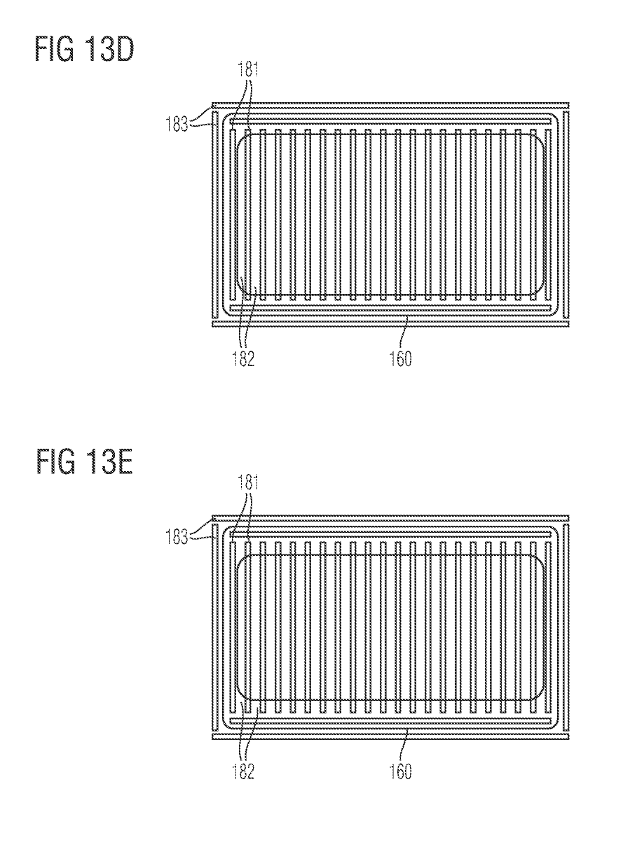

Some embodiments related to a vertical semiconductor device comprising transistor cells in a transistor cell area of a semiconductor body. A first load terminal contact is arranged at a first side of the semiconductor body, see for example the conductive structure 355 of FIG. 8 or the source electrode 157 of FIG. 11. A second load terminal contact is arranged at a second side of the semiconductor body opposite to the first side. A super junction structure is arranged in the semiconductor body, the super junction structure comprising a plurality of first and second semiconductor regions of opposite first and second conductivity types, respectively, and extending in parallel along a first lateral direction and alternately arranged along a lateral direction perpendicular to the first lateral direction, see for example the super junction structures 143 in FIGS. 3, 11. A termination structure may be arranged between an edge of the semiconductor body and the transistor cell area 110 in an edge termination area, see for example the edge termination area 160 of FIG. 11. One or a plurality of third semiconductor regions encircle the transistor cell area. In some embodiments, the plurality of third semiconductor regions are consecutively arranged at lateral distances smaller than a width of the plurality of third semiconductor regions or smaller than a width of the second semiconductor regions, and are of the first conductivity type, see for example FIGS. 13A to 13E. In some embodiments, the one or the plurality of third semiconductor regions includes first dopants of the first conductivity type, and a minimum of a concentration profile of the first dopants along a width direction of the one or the plurality of third semiconductor regions is located in a center of the one or the plurality of third semiconductor regions, respectively, similar to the profiles C2 illustrated in the second semiconductor zone 150a in FIGS. 6A, 6B.

FIGS. 13A to 13E illustrate embodiments of arrangements of first, second, and third semiconductor regions. A part of the semiconductor body 106 surrounding the third semiconductor regions 183 is of the second conductivity type and acts as a lateral field stop region as described with reference to FIGS. 12A and 12B, for example.

In the embodiment illustrated in FIG. 13A, each one of four third semiconductor regions 183 extends along a corresponding one of four longitudinal sides of the semiconductor body.

In the embodiment illustrated in FIG. 13B, along each of the four longitudinal sides of the semiconductor body, a plurality of third semiconductor regions 183 are successively arranged.

In the embodiment illustrated in FIG. 13C, all of the plurality of third semiconductor regions 183 encircling the transistor cell area 110 extend along a same lateral direction.

In the embodiments illustrated in FIGS. 13D, 13E, the first and second semiconductor regions 181, 182 extend into the edge termination area 160. Likewise, the first and second semiconductor regions 181, 182 illustrated in FIGS. 13A, 13B, 13C may extend into the edge termination area 160 similar to FIGS. 13D, 13E. Also the first trenches 111 illustrated in FIGS. 1A, 1B, 1C, 9, and 11 may extend into the edge termination area 160.

Apart from the embodiments illustrated in FIGS. 13A to 13E, other arrangements of the third semiconductor region may be chosen. In some embodiments, a gap of the illustrated third semiconductor regions 183 may be of a same conductivity type than the third semiconductor regions 183 due to lateral diffusion of dopants, for example.

In some embodiments, an integral of a net dopant charge along a width direction between opposite ends of the one or the plurality of elongated third semiconductor regions 183 is smaller than twice a breakdown charge, i.e. smaller than 2×Q_{BR} of the semiconductor material of a drift zone in the semiconductor body 106. As is known, the breakdown charge Q_{BR} is a function of the doping concentration. An avalanche breakdown occurs in a semiconductor material when the electric field strength of an electric field propagating in the semiconductor material exceeds a critical field strength value Ec, which depends on the dopant concentration N_{D} and for which, in case of silicon, a relation Ec=4040×N_{D}^{1/8} [V/cm] holds. Taking into account the critical electric field strength, one can determine the breakdown charge QBR, that is to say the dopant charge in a space charge region before avalanche breakdown is initiated. In case of silicon, the breakdown Q_{BR} charge may be calculated as Q_{BR}(N_{D})=2.67×10¹⁹×N_{D}^{1/8} [ cm⁻²]. In case of non-constant and/or partly compensated doping profiles, technology computer-aided design (TCAD) may be used to calculate Q_{BR}.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device in a semiconductor body of a wafer, the method comprising:
forming a mask on a surface of a semiconductor body, the mask comprising a plurality of first mask openings in a transistor cell area and a mask opening design outside the transistor cell area, wherein the mask opening design includes one second mask opening or a plurality of second mask openings encircling the transistor cell area, the plurality of second mask openings being consecutively arranged at lateral distances smaller than a width of the plurality of second mask openings or smaller than a lateral distance between the first mask openings;
forming a plurality of first trenches in the semiconductor body at the first mask openings and forming one or a plurality of second trenches at the one or the plurality of second mask openings;
filling the first trenches and the one or the plurality of second trenches with a filling material including at least a semiconductor material;
forming a source contact at a first side of the semiconductor body, a drain contact at a second side of the semiconductor body, and a drain ring structure in an area outside the transistor cell area at the first side; and
electrically connecting the semiconductor body and the drain ring structure,
wherein the one or the plurality of second trenches are arranged in an area laterally confined by a dicing street for chip individualization and an inner edge of the drain ring structure, the inner edge of the drain ring structure being closer to the transistor cell area than an outer edge of the drain ring structure.

2. The method of claim 1, wherein a minimum lateral distance between the dicing street and the one or the plurality of second trenches is set smaller than 100 μm.

3. The method of claim 1, wherein a width of the one or the plurality of second trenches is set larger than a width of the plurality of first trenches.

4. The method of claim 1, wherein a ratio of a depth of the one or the plurality of second trenches to a width of the one or the plurality of second trenches is equal to or greater than five.

5. The method of claim 1, further comprising forming a termination structure in an edge termination area between the transistor cell area and the one or the plurality of second trenches.

6. The method of claim 5, wherein the termination structure is formed as one or more of a potential ring structure and a junction termination extension structure.

7. The method of claim 1, further comprising forming a doped well region at least partly overlapping a projection of the plurality of second trenches onto the surface, the doped well region and a drift zone of the semiconductor device having a same conductivity type.

8. The method of claim 1, further comprising, before forming the mask on the surface, increasing a thickness of the semiconductor body by forming a semiconductor layer on the surface, and introducing n- and p-type dopants into the semiconductor layer by a process that is unmasked with respect to the transistor cell area.

9. The method of claim 8, further comprising, after filling the first trenches and the and one or the plurality of second trenches with the filling material, forming a super junction structure by heating the semiconductor layer so as to cause a diffusion process of the n- and p-type dopants toward the filling material, thereby forming net p- and n-doped regions by different diffusion characteristics of the n- and p-type dopants.

10. The method of claim 1, wherein filling the first trenches and the one or the plurality of second trenches with the filling material comprises forming an epitaxial semiconductor layer on sidewalls of the first trenches and the one or the plurality of second trenches.

11. The method of claim 8, wherein the n- and p-type dopants are implanted into the semiconductor layer, and an overall implant dose of the n- and p-type dopants into all of the semiconductor layers differs by at least 20%.

12. A vertical semiconductor device, comprising:
transistor cells in a transistor cell area of a semiconductor body;
a first load terminal contact at a first side of the semiconductor body and a second load terminal contact at a second side of the semiconductor body opposite to the first side;
a super junction structure in the semiconductor body, the super junction structure comprising a plurality of first and second semiconductor regions of opposite first and second conductivity types, respectively, and alternately arranged along a lateral direction perpendicular;
a termination structure between an edge of the semiconductor body and the transistor cell area; and
one or a plurality of third semiconductor regions encircling the transistor cell area and being of the first conductivity type,
wherein a minimum of a concentration profile of first dopants of the first conductivity along a width direction of the one or the plurality of third semiconductor regions is located in a center of the one or the plurality of third semiconductor regions, respectively,
wherein the first load terminal contact is a source contact and the second load terminal contact is a drain contact,
wherein the semiconductor device further comprises a drain ring structure in an area outside the transistor cell area at the first side and electrically connected to the semiconductor body,
wherein the one or the plurality of third semiconductor regions are arranged in an area laterally confined by an edge of the semiconductor body and an inner edge of the drain ring structure, the inner edge of the drain ring structure being closer to the transistor cell area than an outer edge of the drain ring structure.

13. The semiconductor device of claim 12, wherein the one or the plurality of third semiconductor regions encircle the transistor cell area, wherein the plurality of third semiconductor regions are consecutively arranged at lateral distances smaller than a width of the plurality of third semiconductor regions or smaller than a width of the second semiconductor regions.

14. The semiconductor device of claim 12, wherein a minimum lateral distance between the edge of the semiconductor body and the one or the plurality of third semiconductor regions is smaller than 100 μm.

15. The semiconductor device of claim 12, further comprising a doped well region at least partly overlapping a projection of the one or a plurality of third semiconductor regions onto the surface, the doped well region and a drift zone of the semiconductor device having a same conductivity type.

16. The semiconductor device of claim 12, wherein an integral of a net dopant charge along a width direction between opposite ends of the one or the plurality of elongated third semiconductor regions is smaller than twice a breakdown charge of the semiconductor material of a drift zone in the semiconductor body.
